(19) United States
(12) Patent Application Publication
(10) Pub. No.: US 2025/0374836 A1
(43) Pub. Date: Dec. 4, 2025

(54) ELECTRONIC DEVICE COMPRISING A MEMORY CIRCUIT BASED ON PHASE-CHANGE MATERIAL

(71) Applicant: STMicroelectronics International N.V., Geneva (CH)

(72) Inventor: Remy BERTHELON, Crolles (FR)

(73) Assignee: STMicroelectronics International N.V., Geneva (CH)

(21) Appl. No.: 19/202,792

(22) Filed: May 8, 2025

(30) Foreign Application Priority Data
May 29, 2024 (FR) FR2405505

(51) Int. Cl. H10N 70/00; H10B 63/10; H10N 70/20

(52) U.S. Cl. CPC H10N 70/8413; H10B 63/10; H10N 70/011; H10N 70/231

(57) ABSTRACT

The present description concerns a method of manufacturing a device comprising memory cells comprising the following steps: a) forming of trenches in a first insulating layer; b) deposition of a layer made of an electrically-resistive material; c) deposition of a second insulating layer on the layer made of the resistive material; d) anisotropic etching of the second layer and of the layer made of the electrically-resistive material so as to only let them remain on the flanks of the first layer and to form resistive heating elements; e) deposition of a third insulating layer into the trenches, so as to completely fill them; f) deposition of a layer made of a phase-change material on the resistive heating elements and the third layer, wherein the first, second, and third layers are made of silicon nitride.

### BACKGROUND

This application claims the priority benefit of French patent application number 2405505, filed on May 29, 2024, entitled “Dispositif électronique comportant un circuit mémoire à base d'un matériau à changement de phase” which is hereby incorporated by reference to the maximum extent allowable by law.

### TECHNICAL FIELD

The present disclosure generally concerns the field of electronic devices and more particularly aims at the field of electronic chips comprising a memory circuit, based on a phase-change material, and their manufacturing methods.

### DESCRIPTION OF THE RELATED ART

A phase-change material is a material having the ability to change crystalline state under the effect of heat, and more particularly to switch between a crystalline state and an amorphous state, more strongly resistive than the crystalline state. This phenomenon is used to define two memory states, for example 0 and 1, differentiated by the resistance measured through the phase-change material.

There exists a use for improving electronic chips comprising a memory circuit based on a phase-change material.

### BRIEF SUMMARY

For this purpose, an embodiment provides a method of manufacturing an electronic device comprising memory cells arranged in the form of an array of rows and columns comprising the following consecutive steps:
a) forming of trenches in a first insulating layer;
b) deposition of a layer made of an electrically-resistive material;
c) deposition of a second insulating layer on the layer made of the electrically-resistive material;
d) anisotropic etching of the second insulating layer and of the layer of electrically-resistive material so as to only let them remain on the flanks of the first insulating layer and to form, in the layer made of electrically-resistive material, resistive heating elements;
e) deposition of a third insulating layer into the trenches, so as to completely fill them;
f) deposition of a layer made of a phase-change material on top of and in contact with the resistive heating elements and the third insulating layer, wherein the layer made of the phase-change material is common to the memory cells of a same row and the first, second, and third insulating layers are made of silicon nitride.

According to an embodiment, the layer made of the phase-change material, deposited at step f), comprises a lower surface in contact only with the resistive heating elements and with the first, second, and third insulating layers.

According to an embodiment, during step a), at least two trenches are formed in the first insulating layer.

According to an embodiment, during step d), at least three resistive heating elements are formed.

According to an embodiment, during step d), at least four resistive heating elements are formed.

According to an embodiment, the method comprises:
prior to step a), a step g) of deposition of another insulating layer on the upper surface of the first insulating layer; and
between steps e) and f), successively, a step of etching of the third insulating layer, the etching stopping on an upper surface of the other insulating layer, a step of deposition of still another insulating layer, and a step of polishing of the obtained structure so as to expose an upper surface of the first insulating layer.

According to an embodiment, the method comprises, between steps e) and f), a step of polishing of the structure obtained at the end of step e) so as to expose an upper surface of the first insulating layer.

According to an embodiment, the method comprises, prior to step a), a step g) of deposition of another insulating layer on the upper surface of the first insulating layer; and between steps e) and f), successively, a step of etching of the third insulating layer, the etching stopping on an upper surface of the other insulating layer, and a step of polishing of the obtained structure so as to expose an upper surface of the first insulating layer.

Another embodiment provides an electronic device comprising memory cells arranged in the form of an array of rows and columns, each memory cell comprising:
a resistive heating element; and
a layer made of a phase-change material,
the layer made of the phase-change material being common to the memory cells of a same row and covering an upper surface of the resistive heating elements, and
the layer made of the phase-change material being in contact, by a lower surface only, with the resistive heating elements of a same row of memory cells and with insulating layers separating the resistive heating elements, wherein the insulating layers are made of silicon nitride.

According to an embodiment, the phase-change material is a chalcogenide.

According to an embodiment, the resistive heating elements are made of titanium nitride and silicon.

According to an embodiment, the resistive heating elements are “L”-shaped, and comprise a horizontal base and a vertical portion.

According to an embodiment, within a same row, the resistive heating elements of adjacent memory cells alternately have the shape of an “L” and the shape of an inverted “L,” so that a resistive heating element has a neighboring resistive heating element with their horizontal bases facing each other and a neighboring resistive heating element with their vertical portions facing each other.

Another embodiment provides a method of use of an electronic device such as described hereabove, comprising the application of a current to the resistive heating element of one of the memory cells, which results in a change of crystalline phase of the layer made of the phase-change material of the memory cell, allowing the storage of a data bit.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1 is a partial and simplified cross-section view of an example of an electronic device;

FIG. 2 is a partial and simplified cross-section view of an example of an electronic device according to an embodiment;

FIG. 3A, FIG. 3B, FIG. 3C, FIG. 3D, FIG. 3E, FIG. 3F, FIG. 3G, FIG. 3H, FIG. 3I, FIG. 3J, and FIG. 3K are partial and simplified views illustrating steps of an example of a method of manufacturing the electronic device shown in FIG. 2;

FIG. 4A, FIG. 4B, and FIG. 4C are partial and simplified views illustrating steps of another example of a method of manufacturing the electronic device shown in FIG. 2; and

FIG. 5A, FIG. 5B, FIG. 5C, and FIG. 5D are partial and simplified views illustrating steps of still another example of a method of manufacturing the electronic device shown in FIG. 2.

### DETAILED DESCRIPTION

The same elements have been designated by the same references in the various figures. Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front,” “back,” “top,” “bottom,” “left,” “right,” etc., or relative position qualifiers, such as “top,” “bottom,” “upper,” “lower,” etc., or orientation qualifiers, such as “horizontal,” “vertical”, etc., reference is made unless otherwise specified to the orientation of the drawings.

Unless specified otherwise, the expressions “about,” “approximately,” “substantially,” and “in the order of” signify plus or minus 10% or 10°, preferably of plus or minus 5% or 5°.

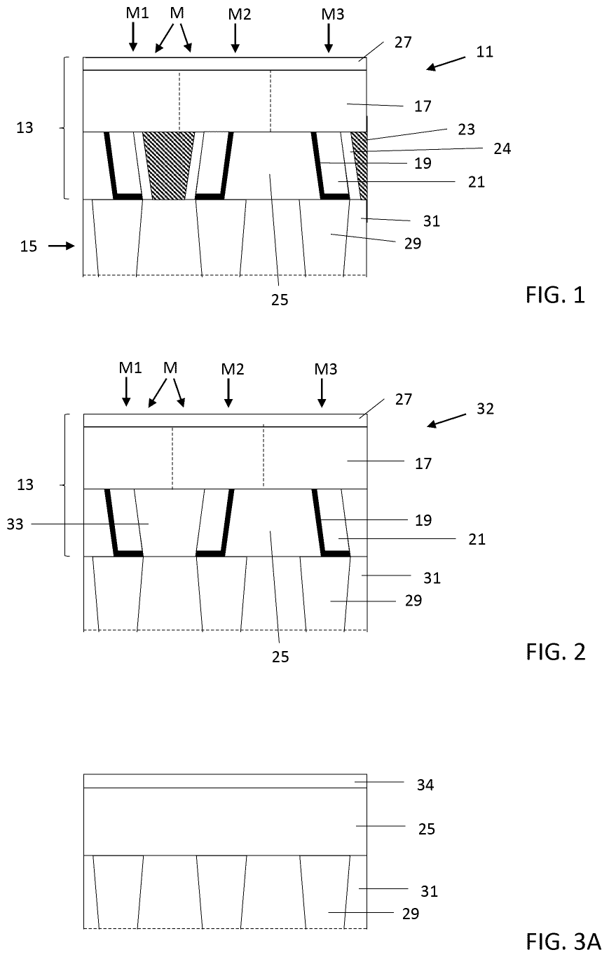

FIG. 1 is a partial and simplified cross-section view of an example of an electronic device 11.

Device 11 is for example an electronic chip.

Device 11 comprises a memory circuit comprising a plurality of memory cells M organized, in top view, in an array of rows and columns. It is respectively spoken of word lines (WL) and of bit lines (BL). As an example, each memory cell M is located at the intersection of a bit line and of a word line.

As an example, the memory cells M shown in FIG. 1 are memory cells M of a same bit line BL. In FIG. 1, only three memory cells M1, M2, M3 are shown. In practice, a memory circuit may comprise a number of memory cells M, per bit line, for example greater than three, for example greater than four.

Memory cells M are phase-change memory cells. As an example, each cell comprises a layer 17 made of a phase-change material, for example a chalcogenide material, for example an alloy of germanium, antimony, and tellurium (GeSbTe) known as GST. Layer 17 has, for example, a thickness in the range from 30 nm to 100 nm, for example, in the order of 50 nm. The memory cells M of a same bit line, for example, comprise a common layer 17. Thus, device 11 for example comprises as many layers 17 as bit lines. Each layer 17 extends in the bit line direction.

In each memory cell M, the phase-change material is, for example, controlled by an electrically-resistive element 19 located under the phase-change material. As an example, element 19 is heated. Element 19 is for example in contact, by its upper surface, with the lower surface of layer 17.

For example, each element 19 has an “L” shape in the cross-section plane of FIG. 1. Each element 19 thus comprises, in its lower portion, a horizontal base and, in an upper portion, a vertical portion. Not all elements 19 have, within a same bit line, the same orientation. As an example, certain elements 19 have the shape of an inverted “L,” that is, their horizontal base is located, in the orientation of FIG. 1, to the left of the vertical portion. As an example, each bit line comprises a succession of elements 19 with an alternation of elements 19 having the shape of an “L” and of 19 elements having the shape of an inverted “L.” As an example, each element 19 is symmetrical, along a vertical plane parallel to the vertical portion of elements 19, with its two neighbors. Two consecutive elements 19 thus have either their bases facing each other or their vertical portions facing each other.

Resistive element 19 is for example made of a metallic material, for example an alloy of nitride, silicon, and titanium (TiSiN).

Two neighboring resistive elements 19 of a same bit line, having their bases facing each other, are separated by a first insulating layer 21 covering the upper surface of the horizontal base of each element 19. The first insulating layer 21 further covers a flank of the vertical portion of the considered element 19. Layer 21 extends, for example, over only part of the height of element 19. Layer 21 extends, for example, along the entire height of the vertical portion of element 19. Layers 21 are for example made of silicon nitride.

Two neighboring resistive elements 19 of a same bit line, having their bases facing each other, are further separated by another insulating layer 23, shown as hatched in FIG. 1. As an example, insulating layer 23 coats the lateral flanks of two distinct neighboring layers 24. As an example, layer 23 extends along the entire height of elements 19. Layer 23 is for example made of silicon oxide.

In the example of FIG. 1, layers 23 and 21 are separated by a layer 24 extending along the entire height of layers 23 and 21.

Layer 24 for example has one of its lateral flanks in contact with the lateral flank of layer 21, opposite to element 19. As an example, layer 24 covers, in a lower portion, the flank of the base of element 19 present in line with layer 21 but not covered by layer 21.

Layer 24 for example has the other of its lateral flank in contact with the lateral flank of the layer 23 that it covers.

As an example, each layer 23 has its two lateral flanks in contact with two distinct neighboring layers 24. As an example, layers 23 have their upper surfaces in contact with the lower surface of layer 17.

As an example, layers 24 are made of silicon nitride.

Two neighboring resistive elements 19 of a same bit line, having their vertical portions facing each other, are separated by an insulating layer 25. Insulating layer 25 thus covers the vertical flanks of the vertical portions of two neighboring elements 19. As an example, layer 25 covers, for each element 19, the flank of its vertical portion, opposite to its base. Layer 25 extends, for example, along the entire height of elements 19.

As an example, the lower surfaces of elements 19, of layers 23, and of layers 24 are coplanar. As an example, the upper surfaces of elements 19, of layers 24, of layers 23, and of layers 21 are coplanar. As an example, heating elements 19 have a thickness in the range from 30 nm to 100 nm, for example in the order of 60 nm.

Layer 17 is topped with a layer 27 made of a conductive material, for example of a metallic material. More precisely, the upper surface of each layer 17 is for example at least partially covered, for example entirely covered, by a layer 27. Each layer 27 extends, preferably in the bit line direction, along the entire length of the layer 17.

As an example, in each memory cell M, metal element 19 and layer 27 respectively form a lower electrode and an upper electrode of memory cell M, and more precisely electrodes of the variable-resistance resistive element formed by layer 17 made of the phase-change material. As an example, the memory cells M of a same bit line are topped by a same layer 27. In other words, the upper electrodes 27 of the memory cells M of the same bit line are interconnected.

As an example, each memory cell M is electrically connected to a selection transistor, not shown. As an example, each memory cell is coupled to the selection transistor which is associated therewith via a conductive via 29. As an example, the upper surface of via 29 is in contact with the lower surface of the element 19 of the associated memory cell M. As an example, vias 29 are made of a conductive material, for example metallic, for example of tungsten. As an example, vias 29 are surrounded by an insulating layer 31, for example made of oxide.

As an example, vias 29 run through an interconnection stack, located between the selection transistors and memory cells M.

The memory cells M of neighboring bit lines are for example insulated from one another by an insulating layer, not shown, for example made of a material having a low dielectric constant or of an oxide.

In such a device, the inventors have found that, over time, within a same bit line, two memory cells M spaced apart by layer 23 age differently from two memory cells M spaced apart by layer 25. Indeed, it has been found that, over a succession of three memory cells M1, M2, and M3, during the storage, for example in memory cell M2, of a 0 and the storage, for example in memory cells M1 and M3, of a 1, the difference in resistance between memory cells M1 and M2 is different from the difference in resistance between memory cells M2 and M3. This behavior difference is linked at least partly to the asymmetry of the structure and to the fact that cells M1 and M2 are separated by a silicon oxide layer 25 in contact with the layer of phase-change material 17, while cells M2 and M3 are not separated by a silicon oxide layer and are only separated by a silicon nitride layer in contact with layer 17.

FIG. 2 is a partial and simplified cross-section view of an example of an electronic device according to an embodiment. More particularly, FIG. 2 illustrates a device 32 similar to device 11, with the difference that layers 23 and 24 are replaced with silicon nitride layers 33.

Each layer 33 is thus in contact, by each of its two lateral flanks, with the lateral flanks of the layers 21 formed in contact with elements 19. As an example, in a lower portion, layers 33 overlap and are in contact with the lateral flanks of the horizontal base of the two surrounding elements 19.

In the embodiment of FIG. 2, the elements 19 of a same bit line are all separated by silicon nitride layers. There thus no longer is, between the elements 19 of a same bit line, any oxide layer.

In the embodiment of FIG. 2, layer 17 is only in contact, by its lower surface, with elements 19 and layers 33 and 21. Thus, layer 17 is not in contact, by its lower surface, with silicon oxide, while this is the case in the embodiment of FIG. 1.

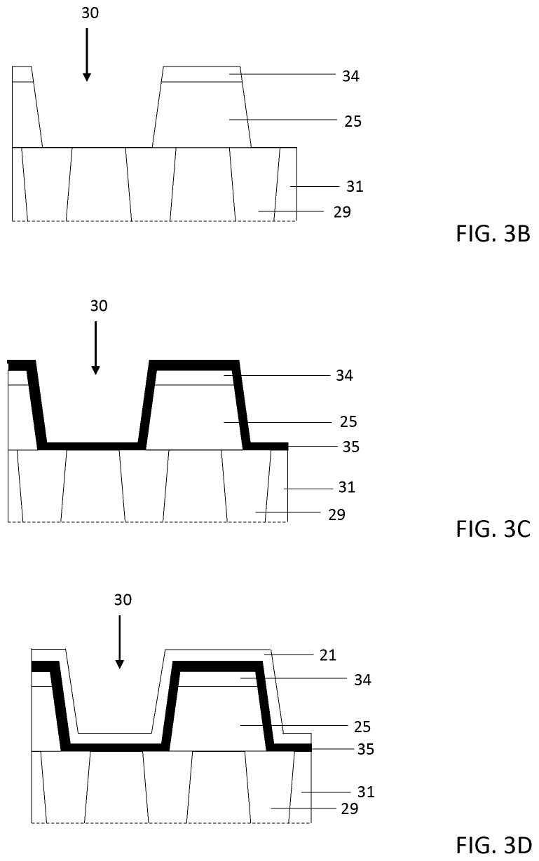

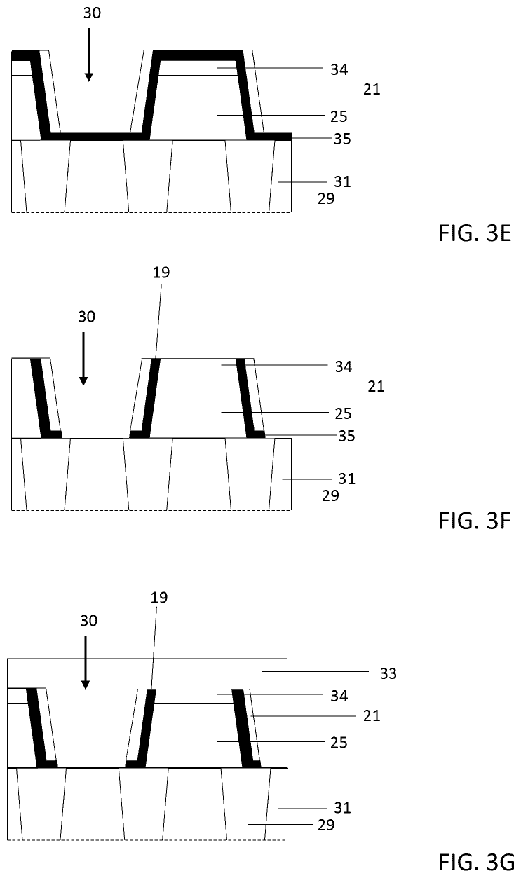

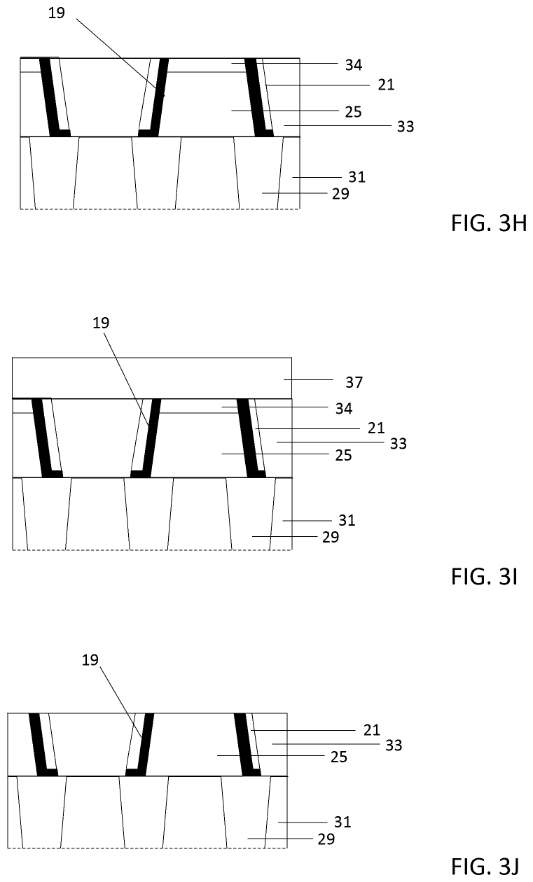

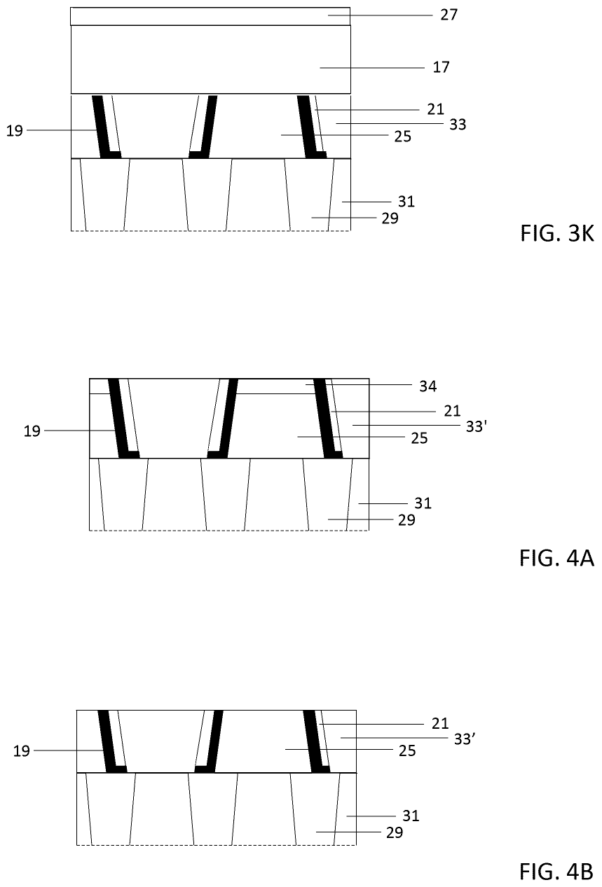

FIG. 3A, FIG. 3B, FIG. 3C, FIG. 3D, FIG. 3E, FIG. 3F, FIG. 3G, FIG. 3H, FIG. 3I, FIG. 3J, and FIG. 3K are partial and simplified views illustrating steps of an example of a method of manufacturing the electronic device shown in FIG. 2.

FIG. 3A illustrates an initial structure comprising vias 29 surrounded by the insulating layer 31 all over which layer 25 has been formed. The initial structure further comprises a layer 34 made of an insulating material, for example different from the material of layer 25, for example of oxide. Layer 34 for example covers layer 25 over its entire surface. As an example, layer 34 is in contact with layer 25.

FIG. 3B illustrates a structure obtained at the end of a step of etching of the layers 25 and 34 of the structure shown in FIG. 3C.

More particularly, during this step, layers 25 and 34 are locally etched to form trenches 30 in the stack of layers 25 and 34 and to expose a portion of the upper surface of layer 31 and of elements 19. During this step, the stack of layers 25 and 34 is for example locally removed from at least a portion of the upper surface of each via 29. At the end of this step, vias 29 thus have their upper surfaces at least partially exposed.

FIG. 3C illustrates a structure obtained at the end of a step of forming of a layer 35 made of the material of the resistive heating element 19 on the upper surface of the structure illustrated in FIG. 3B.

During this step, layer 35 is for example deposited all over the chip surface. As an example, layer 35 is deposited with a thickness in the range from 2 nm to 6 nm, for example in the order of 4 nm.

As an example, during this step, layer 35 is deposited so that it covers, in trenches 30, the upper surface of layer 31 and of via 29 not covered by layer 25, the upper surface of layer 34, and the flanks of layer 34 and of layer 25.

FIG. 3D illustrates a structure obtained at the end of a step of deposition of layer 21 on the upper surface of the structure shown in FIG. 3C.

During this step, layer 21 is for example deposited so as to cover the entire surface of the upper side of layer 34. As an example, layer 21 is conformally deposited. Layer 21 is for example deposited with a thickness in the range from 10 nm to 40 nm.

FIG. 3E illustrates a structure obtained at the end of a step of etching of the layer 21 of the structure shown in FIG. 3D.

More particularly, during this step, layer 21 is etched so that it only remains on the flanks of the stack of layers 25 and 34. Layer 21 is, during this step, for example removed from the upper surface of layer 34 and from the upper surface of vias 29 and of insulating layer 31.

As an example, the etching corresponds to a dry etching, for example a plasma etching. As an example, the etching corresponds to anisotropic etching.

As an example, the etching is, during this step, stopped when the upper surface of layer 35 is exposed.

FIG. 3F illustrates a structure obtained at the end of a step of etching of the layer 35 of the structure shown in FIG. 3E.

More particularly, during this step, layer 35 is etched, only remaining in the portions where it is protected by layer 21. As an example, the etching is, during this step, stopped when the upper surface of layer 34 is exposed.

At the end of this step, layer 35 only remains in a plurality of portions, between layer 21 and the stack of layers 25 and 34, forming elements 19.

FIG. 3G illustrates a structure obtained at the end of a step of deposition of layer 33 on the upper surface of the structure shown in FIG. 3F.

More particularly, during this step, layer 33 is formed so as to cover the upper surface of layer 31 and of vias 29, the upper surface of layer 34, of layer 21, and of elements 19, and the flanks of layer 25 and of elements 19.

As an example, layer 33 is deposited with a sufficiently large thickness so as to completely fill trenches 30 between the stacks of layers 25 and 34. Layer 33 thus has a thickness, in trenches 30, greater than the thickness of the stacks formed by layers 25 and 34.

FIG. 3H illustrates a structure obtained at the end of a step of removal of the upper portion of the structure shown in FIG. 3G.

More particularly, during this step, the upper portion of the structure is removed by etching. As an example, during this step, an upper portion of layer 33 is removed so as to expose the upper surface of layer 34. This step for example enables to level the upper surface of the structure illustrated in FIG. 3G.

FIG. 3I illustrates a structure obtained at the end of a step of deposition of a layer 37 on the upper surface of the structure shown in FIG. 3H.

More particularly, during this step, layer 37 is deposited so as to cover the upper surface of layer 33, the upper surface of layer 34, and the upper surface of layer 21 and of elements 19.

FIG. 3J illustrates a structure obtained at the end of a step of removal of the upper portion of the structure illustrated in FIG. 3I.

More specifically, during this step, the upper portion of the structure is removed by a method of chemical-mechanical polishing (CMP). As an example, the polishing step is stopped when the upper surface of layer 25 is exposed.

FIG. 3K illustrates a structure obtained at the end of a step of deposition of layers 17 and 27 on the upper surface of the structure shown in FIG. 3J.

More particularly, during this step, layers 17 and 27 are successively deposited so that layer 17 covers the entire upper surface of the structure shown in FIG. 3J. As an example, layer 17 is in contact with the upper surface of the structure illustrated in FIG. 3J. More particularly, layer 17 is in contact with the upper surface of layer 25, the upper surface of layer 33, and the upper surface of layer 21 and of stacks 19.

Layer 27 is deposited over the entire surface of layer 17, in contact with layer 17.

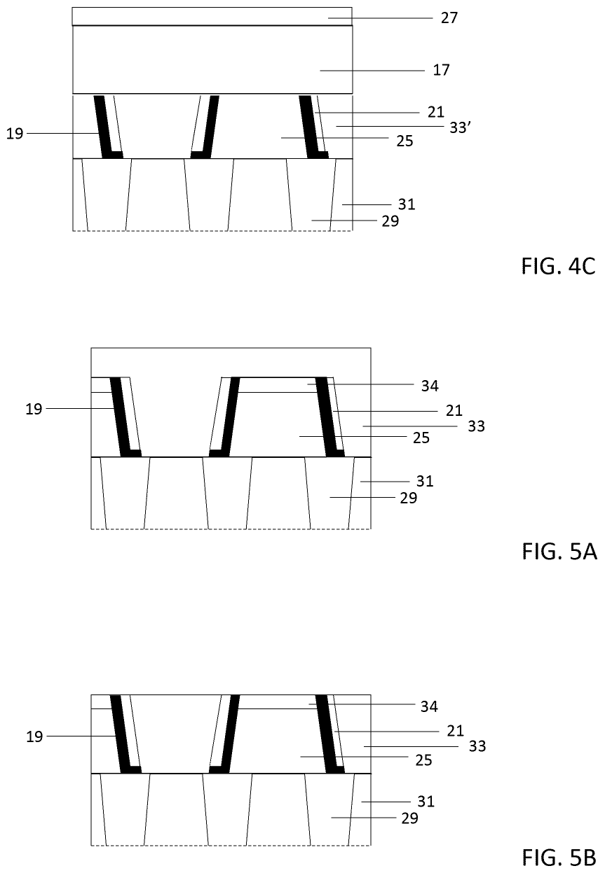

FIG. 4A, FIG. 4B, and FIG. 4C are partial and simplified views illustrating steps of another example of a method of manufacturing the electronic device shown in FIG. 2.

More particularly, the embodiment of FIGS. 4A to 4C differs from the embodiment of FIGS. 3A to 3K in that a chemical-mechanical polishing step replaces the steps of FIGS. 3H to 3J.

FIG. 4A illustrates a structure substantially identical to the structure illustrated in FIG. 3G and obtained at the end of the steps in FIGS. 3A to 3G, with the difference that the structure illustrated in FIG. 4A comprises a layer 33′ similar to the layer 33 of the structure illustrated in FIG. 3A, with the difference that it has a thickness smaller than that of layer 33. As an example, in the structure shown in FIG. 4A, the upper surface of layer 33′ is coplanar with the upper surface of layer 34. As a variant, in the structure illustrated in FIG. 4A, layer 33′ has a thickness, measured above layer 34, lower than a few nanometers.

FIG. 4B illustrates a structure obtained at the end of a step of removal of an upper portion of the structure shown in FIG. 4A.

More particularly, during this step, an upper portion of the structure illustrated in FIG. 4A is removed so as to expose the upper surface of layer 25. As an example, an upper portion of layer 33′, an upper portion of layer 21 and of elements 19, and layer 34 then are removed within one and the same step. The removal is, during this step, carried out by CMP.

FIG. 4C illustrates a structure obtained at the end of a step of deposition of layers 17 and 27 on the upper surface of the structure shown in FIG. 4B.

More particularly, during this step, layers 17 and 27 are deposited substantially identically to what has been described in relation with FIG. 3K.

An advantage of the manufacturing method illustrated in FIGS. 4A to 4C is that it enables to do away with layer 37 and with an etch step.

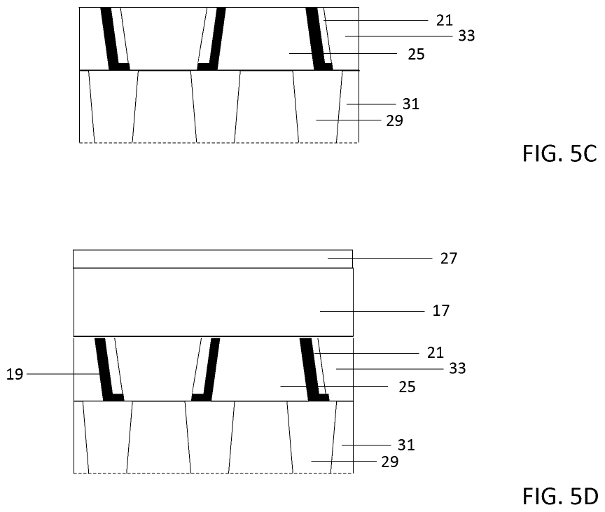

FIG. 5A, FIG. 5B, FIG. 5C, and FIG. 5D are partial and simplified views illustrating steps of still another example of a method of manufacturing the electronic device shown in FIG. 2.

More particularly, the embodiment of FIGS. 5A to 5D differs from the embodiment of FIGS. 3A to 3K in that the step of deposition of layer 37 is omitted.

FIG. 5A shows a structure substantially identical to the structure shown in FIG. 3G and obtained at the end of the steps of FIGS. 3A to 3G, with the difference that, in the structure shown in FIG. 5A, layer 34 has a thickness greater than that of the layer 34 of the structure shown in FIG. 3A. Indeed, this thickness difference enables to perform a chemical-mechanical polishing directly on the structure shown in FIG. 5A with no prior deposition of layer 37.

FIG. 5B illustrates a structure obtained at the end of a step of removal of an upper portion of the structure shown in FIG. 5A.

More particularly, during this step, the upper portion of the structure is removed by etching. As an example, during this step, an upper portion of layer 33 is removed to expose the upper surface of layer 34. This step is for example used to level the upper surface of the structure shown in FIG. 5A.

FIG. 5C illustrates a structure obtained at the end of a step of removal of an upper portion of the structure shown in FIG. 5B.

More particularly, during this step, an upper portion of the structure illustrated in FIG. 5C is removed to expose the upper surface of layer 25. As an example, an upper portion of layer 33, an upper portion of layer 21 and of elements 19 and layer 34 are removed within one and the same step. The removal is, during this step, carried out by CM P.

FIG. 5D illustrates a structure obtained at the end of a step of deposition of layers 17 and 27 on the upper surface of the structure shown in FIG. 5C.

More particularly, during this step, layers 17 and 27 are deposited substantially identically to what has been described in relation with FIG. 3K.

An advantage of the manufacturing method illustrated in FIGS. 5A to 5D is that it enables to do away with the deposition of layer 37.

Various embodiments and variants have been described. The person skilled in the art will understand that certain features of these various embodiments and variants could be combined, and other variants will become apparent to the person skilled in the art.

In particular, although embodiments have been described in which memory elements M are formed above the interconnection stack, the embodiments are not limited to this specific case. As a variant, memory elements M may be formed between the interconnection stack and vias 29.

Further, although embodiments comprising an insulating etch stop layer 34 have been described, this layer is optional. It can then be provided to control the etch steps differently, for example by controlling the etching time or the etching speed.

Finally, the practical implementation of the described embodiments and variants is within the abilities of those skilled in the art, based on the indications given above.

A method of manufacturing an electronic device is summarized as including memory cells (M) arranged in the form of an array of rows and columns, including the following consecutive steps: a) forming of trenches (30) in a first insulating layer (25); b) deposition of a layer of made of an electrically-resistive material (35); c) deposition of a second insulating layer (21) on the layer made of the electrically-resistive material (35); d) anisotropic etching of the second insulating layer (21) and of the layer made of the electrically-resistive material (35) to only let them remain on the flanks of the first insulating layer (25) and to form, in the layer made of the electrically-resistive material, resistive heating elements (19); e) deposition of a third insulating layer (33; 33′) into the trenches (30), so as to completely fill them; and f) deposition of a layer made of a phase-change material (17) on top of and in contact with the resistive heating elements (19) and the third insulating layer (33; 33′), wherein the layer made of the phase-change material is common to the memory cells (M) of a same row and the first, second, and third insulating layers (21, 33, 25; 21, 33′, 25) are made of silicon nitride.

The layer made of the phase-change material (17), deposited at step f) includes a lower surface in contact only with the resistive heating elements (19) and with the first, second, and third insulating layers (21, 33, 25; 21, 33′, 25).

During step a), at least two trenches (30) are formed in the first insulating layer (25).

During step d), at least three resistive heating elements (19) are formed.

During step d), at least four resistive heating elements (19) are formed.

The method includes: before step a), a step g) of deposition of another insulating layer (34) on the upper surface of the first insulating layer (25); and between steps e) and f) successively, a step of etching of the third insulating layer (33; 33′), the etching stopping on an upper surface of the other insulating layer (34), a step of deposition of still another insulating layer (37), and a step of polishing of the obtained structure so as to expose an upper surface of the first insulating layer (25).

The method includes between steps e) and f), a step of polishing of the structure obtained at the end of step e) so as to expose an upper surface of the first insulating layer (25).

The method includes before step a), a step g) of deposition of another insulating layer (34) on the upper surface of the first insulating layer (25); and between steps e) and f) successively, a step of etching of the third insulating layer (33; 33′), the etching stopping on an upper surface of the other insulating layer (34), and a step of polishing of the obtained structure so as to expose an upper surface of the first insulating layer (25).

an electronic device is summarized as including memory cells (M) arranged in the form of an array of rows and columns, each memory cell (M) includes: a resistive heating element (19); and a layer made of a phase-change material (17), the layer made of the phase-change material being common to the memory cells (M) of a same row and covering an upper surface of the resistive heating elements (19), and the layer made of the phase-change material being in contact, by a lower surface only with the resistive heating elements (19) of a same row of memory cells (M) and with insulating layers (21, 33, 25; 21, 33′, 25) separating the resistive heating elements (19), wherein the insulating layers (21, 33, 25; 21, 33′, 25) are made of silicon nitride.

The phase-change material is a chalcogenide.

The resistive heating elements (19) are made of titanium silicon nitride.

The resistive heating elements (19) are “L”-shaped and include a horizontal base and a vertical portion.

Within a same line, the resistive heating elements (19) of neighboring memory cells (M) alternately have the shape of an “L” and the shape of an inverted “L,” so that a resistive heating element (19) has a neighboring resistive heating element (19) with their horizontal bases facing each other and a neighboring resistive heating element (19) with their vertical portions facing each other.

The method of use of an electronic device (11) includes the application of a current in the resistive heating element (19) of one of the memory cells (M), which results in a change of crystalline phase of the layer made of the phase-change material (17) of the memory cell (M), allowing the storage of a data bit.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of manufacturing an electronic device including:
forming a plurality of trenches in a first insulating layer, each of the plurality of trenches having an opening with a first width along a first direction that is greater than a second width of a first surface of each trench, each first surface being opposite the opening along a second direction transverse to the first direction;
depositing a layer of an electrically-resistive material into the plurality of trenches;
depositing a second insulating layer on the layer of the electrically-resistive material;
forming a plurality of resistive heating elements by etching the second insulating layer and the layer of the electrically-resistive material, leaving portions of the second insulating layer and the layer of the electrically-resistive material on flanks of the first insulating layer;
depositing a third insulating layer into the trenches, completely filling the trenches; and
depositing a layer of a phase-change material on top of and coupled to the resistive heating elements and the third insulating layer,
wherein the layer of the phase-change material is common to a plurality of memory cells of a same row and the first, second, and third insulating layers include silicon nitride.

2. The method according to claim 1, wherein the layer of the phase-change material includes a first surface in contact only with the resistive heating elements and with the first, second, and third insulating layers.

3. The method according to claim 1, wherein, during the forming the plurality of trenches, at least two trenches are formed in the first insulating layer.

4. The method according to claim 1, wherein, during the forming the plurality of resistive heating elements, at least three resistive heating elements are formed.

5. The method according to claim 4, wherein, during the forming the plurality of resistive heating elements, at least four resistive heating elements are formed.

6. The method according to claim 1, comprising:
before the forming the plurality of trenches, depositing a fourth insulating layer on a first surface of the first insulating layer; and
between depositing the third insulating layer and depositing the layer of the phase-change material, etching the third insulating layer, the etching stopping on a first surface of the fourth insulating layer, depositing a fifth insulating layer, and polishing the first surface of the fourth insulating layer and the third insulating layer to expose a first surface of the first insulating layer.

7. The method according to claim 1, comprising, between depositing the third insulating layer and depositing the layer of the phase-change material, polishing the third insulating layer to expose a first surface of the first insulating layer.

8. The method according to claim 1, comprising before the forming the plurality of trenches, depositing a fourth insulating layer on a first surface of the first insulating layer; and
between depositing the third insulating layer and depositing the layer of the phase-change material, etching the third insulating layer, the etching stopping on a first surface of the fourth insulating layer, and polishing the fourth insulating layer and the third insulating layer to expose a first surface of the first insulating layer.

9. An electronic device, comprising
a plurality of memory cells arranged in an array of rows and columns, each memory cell including:
a resistive heating element having a first, base portion and a second portion transverse to the first portion, an angle between the first portion and the second portion being obtuse; and
a layer of a phase-change material, the layer of the phase-change material being common to the plurality of memory cells of a first row and covering a first surface of the resistive heating elements, the layer of the phase-change material being coupled, by a second surface opposite the first surface, with the resistive heating elements of the first row of memory cells and with insulating layers separating the resistive heating elements,
wherein the insulating layers include silicon nitride.

10. The device according to claim 9, wherein the phase-change material is a chalcogenide.

11. The device according to claim 9, wherein the resistive heating elements include titanium silicon nitride.

12. The device according to claim 9, wherein the first, base portion of each resistive heating element is coupled to a connective via.

13. The device according to claim 12, wherein, within the first row of memory cells in the array, the resistive heating elements of adjacent memory cells alternately have a shape of an “L” and a shape of an inverted “L,” each first, base portion of each resistive heating element faces the first, base portion of an adjacent resistive heating element and each second portion of each resistive heating element faces the second portion of an adjacent resistive heating element.

14. A method, comprising:
forming a trench through a first insulating layer to a first conductive via;
forming a resistive heating layer in the trench, the resistive heating layer covering a plurality of sidewalls of the trench and a first surface of the trench that includes the first conductive via, the first surface of the trench having a first width along a first direction smaller than a second width of an opening of the trench along the first direction;
forming a second insulating layer in the trench, on the resistive heating layer;
exposing the first surface of the trench by etching the resistive heating layer and the second insulating layer; and
forming a phase-change layer on the first insulating layer, the resistive heating layer, and the second insulating layer.

15. The method according to claim 14, wherein the first surface of the trench includes the first conductive via, a second conductive via, and a dielectric layer.

16. The method according to claim 14, comprising, after the exposing the first surface of the trench, forming a third insulating layer entirely filling the trench, the third insulating layer being directly on the first conductive via, the resistive heating layer, and the second insulating layer.

17. The method according to claim 14, comprising forming a conductive layer on the phase-change layer.

18. The method according to claim 16, further comprising a fourth insulating layer on the first insulating layer, the forming the phase-change layer including forming the phase-change layer on the fourth insulating layer.

19. The method according to claim 18, further comprising, after the forming the third insulating layer, etching entirely through the fourth insulating layer to expose the first insulating layer.

20. The method according to claim 14, wherein the phase-change layer has a thickness in the range of 2 nm and 6 nm.
